(19) United States
(12) Patent Application Publication
(10) Pub. No.: US 2011/0111582 A1
(43) Pub. Date: May 12, 2011

(54) METHOD FOR DEPOSITING ULTRA FINE GRAIN POLYSILICON THIN FILM

(76) Inventors: Hai Won Kim, Gyeonggi-do (KR); Sang Ho Woo, Gyeonggi-do (KR); Sung Gil Cho, Gyeonggi-do (KR); Song Hwan, Park (KR); Kyung Soo Jung, Gyeonggi-do (KR)

(21) Appl. No.: 12/990,629

(22) PCT Filed: Apr. 29, 2009
(86) PCT No.: PCT/KR09/02266

§ 371 Date: Jan. 24, 2011

(30) Foreign Application Priority Data
May 2, 2008 (KR) 10-2008-0041177

(51) Int. Cl. H01L 21/285

(52) U.S. Cl. 438/585; 257/E21.179

(57) ABSTRACT

Disclosed is a method for depositing a polysilicon thin film with ultra-fine crystal grains. According to the present invention, the polysilicon thin film is deposited on a substrate by supplying source gases inside a chamber in which the substrate is loaded, wherein the source gases include a silicon-based gas and an oxygen-based gas. The mixing ratio of the oxygen-based gas to the silicon-based gas may be 0.15 or less (excluding 0). The oxygen within the thin film may be 20 atomic % (atomic percentage) or less (excluding 0).

### TECHNICAL FIELD

The present application relates to a method for depositing a thin film, and more particularly a method for depositing a thin film using a chemical vapor deposition (CVD).

### BACKGROUND ART

A semiconductor manufacturing process generally comprise a deposition process of depositing a thin film on a wafer surface, and various types of thin films including a silicon oxide, a polycrystalline silicon, and a silicon nitride are deposited on the wafer surface.

The chemical vapor deposition (CVD) process in various deposition processes is forming the thin file on a substrate surface by thermal decomposition or a reaction of a gas compound, that is, desired materials are deposited on the substrate surface from gas phase.

In the deposition process, the method for deposing the polycrystalline silicon film on the wafer surface is as follows.

First, the wafer is loaded in a deposition chamber and then a thin film is deposited on the wafer by supplying a source gas in the chamber. In this time, the source gas supplied in the chamber includes silane (SiH₄) and the thin film is deposited on the wafer by the source gas supplied in the chamber. In this time, the polycrystalline silicon film is deposited on the wafer by thermal decomposition of silane (SiH₄).

However, by the above-mentioned deposition process, it has been difficult to deposit not only a polycrystalline silicon film having silicon crystal structure of thin thickness (less than about 400 Å) but also an uniform polycrystalline silicon film. Accordingly, when the polycrystalline silicon film is used as a floating gate electrode of a semiconductor flash memory, there are some problems such as over erase phenomenon in the manufactured device and thereby characteristics of the device such evenness, durability and reliability of the device are degraded by threshold voltage shift and very uneven threshold voltage.

More particularly, an amorphous silicon thin film is firstly grown at a constant process temperature (usually less than 55° C.) by using silane (SiH₄) or disilane (Si₂H₆) and then the grown thin film is crystallized by a subsequent predetermined heat treatment process (for example, 650° C. to 900° C.). Consequently, results as shown in FIG. 1 are obtained. FIG. 1 is the photograph of the polycrystalline silicone film according to the conventional deposition process, which are taken by a Transmission Electron Microscope (TEM).

When the gate electrode of the device such as the flash memory is formed by the above-mentioned processes, sizes of crystallized grains(dark portions in FIG. 1) of the thin film are very irregular and crystal grains having sizes of tens of Å or few hundreds of nm are formed. Thus, when a transistor is formed by using such process, one or two grain boundaries are formed in regions where the size of grains is large, and on the contrary, many grain boundaries are formed in regions where the size of grains is very small. Therefore, in the region where crystal grains are very small and thus many grain boundaries are formed, an oxide valley region is formed by tunnel oxide under the region where the crystal grains are contacted to each other. A lager oxide valley is formed under an interface between larger crystal grains. Accordingly, more phosphorus is concentrated in the oxide valley region at the subsequent process of forming phosphorus polycrystalline silicon so as to reduce a local barrier height. Thereby, it may cause reliability of the device to be largely degraded because the over erase point or electron trap formation site is formed by the concentrated phosphorus at the time of driving the device. That is, differences between moving speeds of electrons by the over erase or the electron trap causes differences of driving characteristics between the transistors. As a result, there are problems that characteristics of the devices including the transistors are terribly degraded because the driving characteristics of transistors included in one chip are largely different from each other when the device is driven.

### DISCLOSURE

### Technical Problem

Accordingly, an object of the present invention is to provide a method for depositing an ultra fine grain polysilicon thin film that can prevent characteristics of the device to be degraded by improving a degree of uniformity of electrical characteristics.

### Technical Solution

According to an embodiment of the present invention, there is a method for depositing an ultra fine grain polysilicon thin film, the method comprises: depositing the polysilicon thin film on a substrate by supplying source gas in a chamber loaded with the substrate, wherein the source gas includes silicon-based gas and oxygen-based gas.

A mixing ratio of the oxygen-based gas to the silicon-based gas may be equal to or less than 0.15 (except for 0) in the source gas.

Content of the oxygen in the polysilicon thin film may be equal to or less than 20 atomic % (except for 0).

The deposition process may be performed at temperatures of 580 to 650° C. and pressure of 100 to 300 torr.

The deposition process may be performed at temperatures of 650 to 750° C. and pressure of 5 to 100 torr.

The method may further comprise heat treatment processing the thin film.

The silicon-based gas comprises one of silane (SiH₄), disilane (Si₂H₆), Dichlorosilane (DCS), Trichlorosilane (TCS) and Hexachlorosilane (HCD).

The oxygen-based gas comprises one of N₂O, NO, O₂.

### Advantageous Effects

According to the method for depositing an ultra fine grain polysilicon thin film of the present invention, the method can prevent characteristics of the device to be degraded by improving a degree of uniformity of electrical characteristics when the thin film is deposited on a substrate using a chemical vapor desposition because the ultra fine grain polysilicon thin film is deposited on the substrate by supplying source gas including silicon-based gas and oxygen-based gas in a chamber loaded with the substrate

In addition, the present invention uses silane (SiH₄) gas as silicon source gas and the size of grains is controlled in the deposition process by mixing nitrogen-containing gas such as NH3 with SiH3 in a predetermined ratio and injecting the mixed gas under predetermined process temperature and pressure. Accordingly, when the polysilicon thin film is used as the electrode of the floating gate of the flash memory in the semiconductor device, uniform crystal grains can be formed and thereby durability and reliability of the device can be obtained. In addition, when the polysilicon thin film is used in Dynamic Random Access Memory (DRAM), Static Random Access Memory (SRAM) and LOGIC device, excellent device characteristics can be secured and thus yield and characteristics of this semiconductor device can be improved by manufacturing the device using the polysilicon thin film.

### DESCRIPTION OF DRAWINGS

FIG. 1 is a photograph illustrating a polycrystalline silicon film having a large size of grains according to a conventional deposition method.

FIG. 2 is a conceptual diagram of a thin film deposition apparatus according to the embodiment of the present invention.

FIG. 3 is a graph illustrating characteristics of the polysilicon thin film formed by the method for depositing the ultra fine grain polysilicon thin film according to the embodiment of the present invention, and particularly the graph shows a refractive index according to a mixing ratio of oxygen source gas and silicon source gas.

FIGS. 4 and 5 are TEM photographs illustrating crystal structures of thin films deposited by the method for depositing the ultra fine grain polysilicon thin film according to the embodiment of the present invention.

FIGS. 6 and 7 are a table and a graph illustrating a value of converting concentration of oxygen into atomic percentage (atomic %) and grain sizes according to the mixing ratio of oxygen source gas and silicon source gas.

### BEST MODE

Hereinafter, preferred embodiments of the present invention will be described in details with reference to the accompanying drawings. The embodiments of the present invention can be changed in various forms and thus the present invention is not limited to the embodiments disclosed hereinafter. The embodiments are provided to assist those of ordinary skill in the art in comprehensive understanding of the present invention and thus configurations of the respective elements can be exaggerated to emphasize the feature of the present invention and explain the present invention more clearly.

According to an exemplary embodiment of the present invention, when a thin film is deposited on a substrate using a chemical vapor deposition process, an ultra fine grain polysilicon thin film is to be deposited by depositing the thin film on a substrate by supplying source gas including silicon-based gas, nitrogen-based gas and phosphorous-based gas in a chamber loaded with the substrate.

Generally, the “chemical vapor deposition” is a process of forming a thin film on a semiconductor substrate by supplying source gas in gas state to a substrate and inducing chemical reaction between the source gas and the substrate. Referring to FIG. 2, the chemical vapor deposition process performed in a single chamber according to the embodiment of the present invention will be explained. FIG. 2 shows a deposition apparatus for performing a deposition process according to the embodiment of the present invention.

An introducing unit 12 is formed in a chamber 11 of the deposition apparatus 10 to introduce source gas. Gas introduced by the introducing unit 12 is sprayed into the chamber 11 through a shower head 13. In addition, a wafer 15 for deposition is placed on a heater 14, which is supported by a heater support 16. After performing deposition by the deposition apparatus, unreacted gas is discharged through a vacuum port 17.

Firstly, the substrate is transferred into the chamber 11. Then, silane (SiH₄) gas and inert N₂ gas are introduced into the chamber 11 as carrier gas, and the reaction gas decomposed by thermal decomposition is deposited via surface travels on a silicon substrate positioned in the chamber 11 by a chemical vapor deposition process of a single wafer type. At this time, if N₂O gas is injected in a predetermined ratio together with SiH₄ into the reaction chamber 11, silicon atoms in the thermal decomposed gas is not proceed with nucleation and grain growth by the oxygen atoms and thus it is possible to deposit the polycrystalline silicon in amorphous state at high temperature (650° C. or more).

In the process, a mixing ratio of N₂O/SiH₄ gases is the most important factor in the present invention because silicon oxide can be deposited when the mixing ratio of two reaction gases is maintained over certain level.

In order to form the polycrystalline silicon having ultra fine grain structures, subsequent thermal treatment process is performed over a predetermined temperature using a reaction chamber of furnace type or single wafer type.

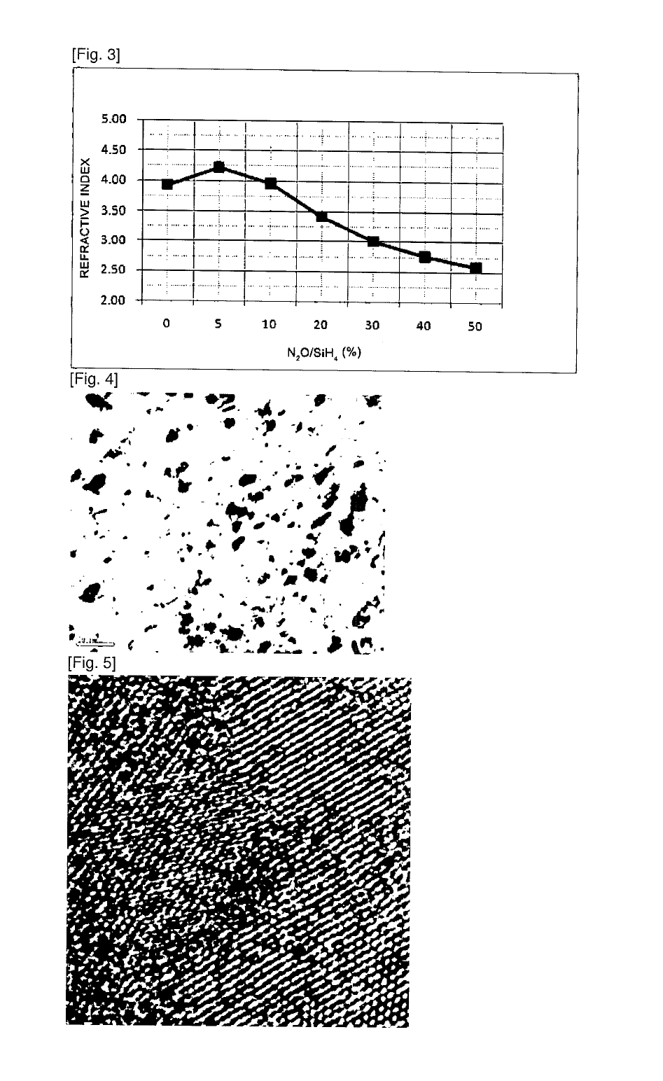

FIG. 3 is a graph illustrating characteristics of the polysilicon thin film formed by the method for depositing the ultra fine grain polysilicon thin film according to the embodiment of the present invention, and particularly the graph shows a refractive index according to a mixing ratio of oxygen source gas and silicon source gas.

FIG. 3 shows a refractive index according to a mixing ratio of N₂O and SiH₄ and referring to FIG. 3, the horizontal axis corresponds to the mixing ratio of N₂O and SIH₄ and the vertical axis corresponds to the refractive index (R.I.) indicating crystalline characteristics of the deposited thin film. As shown in the FIG. 3, the refractive index tends to be reduced as the ratio of N₂O mixed with SiH₄ increases. When the refractive index value is maintained within the scope of 3.8 to 4.5, amorphous or polycrystalline silicon thin film deposition is formed. On the contrary, when refractive index value is less than 3.8, the thin film having a characteristic near SiO₂ of Si rich is deposited.

Therefore, considering the refractive index, it is advantageous to maintain the mixing ratio of N₂O mixed with SiH₄ equal to or less than 15% (or 0.15) and amorphous or polycrystalline silicon thin film deposition is accomplished when the mixing ratio is within this scope.

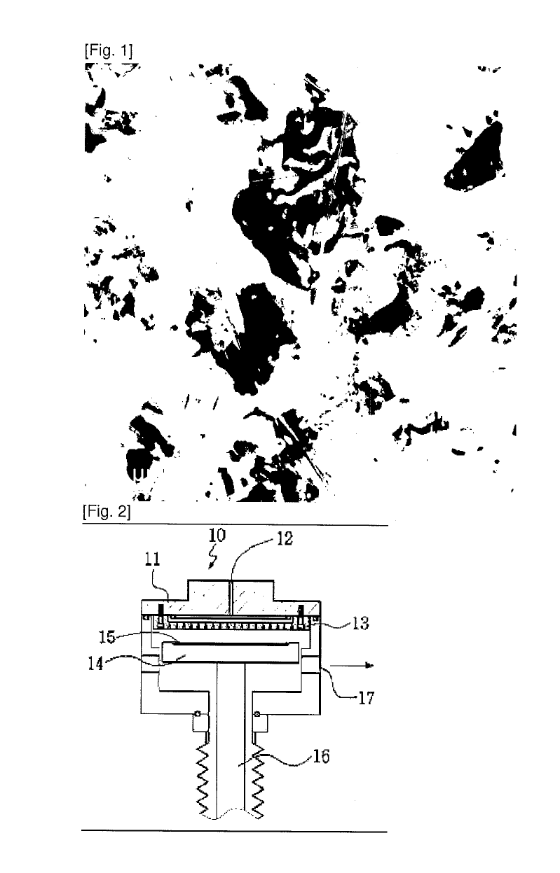

FIGS. 4 and 5 are TEM photographs illustrating crystal structures of thin films deposited by the method for depositing the ultra fine grain polysilicon thin film according to the embodiment of the present invention. Dark portions in FIG. 4 show grains and the grains shown in FIG. 4 are finer than those of FIG. 1.

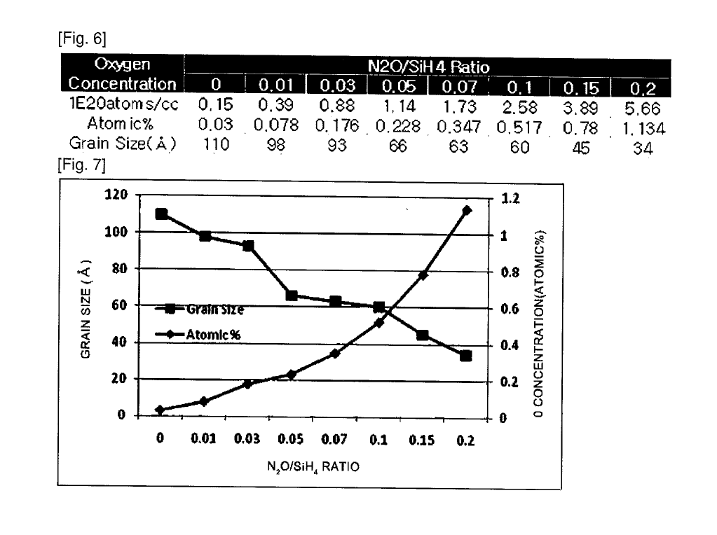

FIGS. 6 and 7 are a table and a graph illustrating a value of converting concentration of oxygen into atomic percentage (atomic %) and grain sizes according to the mixing ratio of oxygen source gas and silicon source gas.

Referring to FIGS. 6 and 7, it shows that the oxygen in the thin film is 0.78 atomic % when the mixing ratio of N₂O mixed with SiH₄ is 15% (or 0.15) and it is preferable to maintain the nitrogen in the thin film about 0.78 atomic % or less from FIGS. 6 and 7. When the oxygen in the thin film is 0.78 atomic %, a grain size is approximately 45 angstroms.

FIGS. 8 and 9 are a table and a graph illustrating a concentration of phosphorus and grain sizes according to the flow rate of the PH3 when the phosphorus doping is done by the method of in-situ in the specific concentration condition of oxygen.

In the above embodiment, SiH₄ was used as the Si source gas and N₂O was used as the oxygen source gas. However, it will be understood by those skilled in the art that the thin film having ultra fine grain structures may be formed by injecting disilane (Si₂H₆), Dichlorosilane (DCS), Trichlorosilane (TCS) and Hexachlorosilane (HCD) and other gas including Si as Si source gas, or NO, O₂, and other gas including oxygen as oxygen source gas in a predetermined mixing ratio of N₂O/SiH₄ into the reaction chamber under constant temperature and pressure.

As such, the present invention deposits the ultra fine grain polysilicon thin film by depositing the thin film on a substrate by supplying source gas including silicon-based gas, oxygen-based gas and phosphorous-based gas in a chamber loaded with the substrate when the thin film is deposited by the chemical vapor deposition process.

While the invention has been described with reference to specific preferred embodiments, it will be understood by those skilled in the art that other embodiments may be possible. Therefore, the technical concept and scope of the following claims are not limited to the preferred embodiments.

### INDUSTRIAL APPLICABILITY

The present invention can be applied to various apparatus including deposition process.

1. A method for depositing an ultra fine grain polysilicon thin film, comprises:
depositing the polysilicon thin film on a substrate by supplying source gas in a chamber loaded with the substrate,
wherein the source gas includes silicon-based gas and oxygen-based gas.

2. The method of claim 1, wherein a mixing ratio of the oxygen-based gas to the silicon-based gas may be equal to or less than 0.15 (except for 0) in the source gas.

3. The method of claim 1, wherein content of the the oxygen in the polysilicon thin film may be equal to or less than 0.8 atomic % (except for 0).

4. The method of claim 1, wherein the deposition process may be performed at temperatures of 580 to 650° C. and pressure of 100 to 300 torr.

5. The method of claim 1, wherein the deposition process may be performed at temperatures of 650 to 750° C. and pressure of 5 to 100 torr.

6. The method of claim 1, wherein the method may further comprise heat treatment processing the thin film.

7. The method of claim 1, wherein the silicon-based gas comprises one of silane (SiH₄), disilane (Si₂H₆), Dichlorosilane (DCS), Trichlorosilane (TCS) and Hexachlorosilane (HCD).

8. The method of claim 1, wherein the oxygen-based gas comprises one of N₂O, NO, O₂.
